(19) United States
(12) Patent Application Publication
(10) Pub. No.: US 2024/0336840 A1
(43) Pub. Date: Oct. 10, 2024

(54) Etching Compositions

(71) Applicant: Fujifilm Electronic Materials U.S.A., Inc., N. Kingstown, RI (US)

(72) Inventor: Atsushi Mizutani, Shizuoka (JP)

(21) Appl. No.: 18/624,450

(22) Filed: Apr. 2, 2024

Related U.S. Application Data
(60) Provisional application No. 63/457,841, filed on Apr. 7, 2023.

(51) Int. Cl. C09K 13/08; H01L 21/311

(52) U.S. Cl. CPC C09K 13/08; H01L 21/31111

(57) ABSTRACT

The present disclosure is directed to etching compositions that are useful for, e.g., selectively hafnium oxide from a semiconductor substrate as an intermediate step in a multistep semiconductor manufacturing process.

### CROSS-REFERENCE TO RELATED APPLICATION

The present application claims priority to U.S. Provisional Application Ser. No. 63/457,841, filed on Apr. 7, 2023, the contents of which are hereby incorporated by reference in their entirety.

### FIELD OF THE DISCLOSURE

The present disclosure relates to etching compositions and processes of using etching compositions. In particular, the present disclosure relates to etching compositions that can selectively etch hafnium oxides in the presence of other exposed or underlying materials, such as metal conductors (e.g., copper), gate materials (e.g., SiGe), barrier materials, and insulator materials (e.g., low-k dielectric materials).

### BACKGROUND OF THE DISCLOSURE

The semiconductor industry is rapidly decreasing the dimensions and increasing the density of electronic circuitry and electronic components in microelectronic devices, silicon chips, memory chips, liquid crystal displays, MEMS (Micro Electro Mechanical Systems), printed wiring boards, and the like. The integrated circuits within them are being layered or stacked with insulating layers having constantly decreasing thicknesses between each circuitry layer. As the feature sizes have shrunk, patterns have become smaller, and device performance parameters tighter and more robust. As a result, various issues which heretofore could be tolerated can no longer be tolerated or have become more of an issue due to the smaller feature size.

In the production of advanced integrated circuits, to minimize problems associated with the higher density and to optimize performance, both high k and low k insulators, and assorted barrier layer materials have been employed.

Hafnium oxides (HfOx) can be utilized in the manufacturing of semiconductor devices, liquid crystal displays, MEMS (Micro Electro Mechanical Systems), printed wiring boards and the like. Hafnium oxides frequently needs to be removed in the presence of other exposed or underlying materials in a semiconductor substrate during an etching process.

### SUMMARY OF THE DISCLOSURE

In the construction of semiconductor devices, hafnium oxides (HfOx such as HfO₂) frequently needs to be etched. In the various types of uses and device environment of HfOx, other layers are in contact with or otherwise exposed at the same time as this material is etched. Highly selective etching of the HfOx in the presence of these other materials (e.g. metal conductors, dielectrics, channel materials, gate materials, and hard masks) is typically needed for device yield and long life.

The present disclosure relates to compositions and processes for selectively etching HfOx relative to hard mask layers (e.g., SiOx), gate materials (e.g., SiGe or SiOx) and/or low-k dielectric layers (e.g., SiOx, carbon doped oxide, SiCO, or silicon oxycarbonitride (SiOCN)) that are present in the semiconductor device using an etching composition described herein. More specifically, the present disclosure relates to compositions and processes for selectively etching HfOx relative to SiOx.

In one aspect, this disclosure features an etching composition that includes (1) at least one first acid or a salt thereof, the at least one first acid including a fluorine-containing inorganic acid; (2) at least one second acid different from the at least one first acid, the at least one second acid having a pKa of at most about 3; (3) at least one organic solvent having a logP of from about-0.2 to about 1.6; and (4) water.

In another aspect, this disclosure features an etching composition that includes (1) at least one first acid or a salt thereof, the at least one first acid including a fluorine-containing inorganic acid; (2) at least one second acid different from the at least one first acid, the at least one second acid having a pKa of at most about 3; (3) at least one organic solvent having a ClogP of from about-0.3 to about 1.6; and (4) water.

In another aspect, this disclosure features a method that includes contacting a semiconductor substrate supporting a hafnium oxide film (e.g., in a HfOx-containing feature) with an etching composition described herein to substantially remove the hafnium oxide film.

In still another aspect, this disclosure features an article formed by the method described above, in which the article is a semiconductor device (e.g., an integrated circuit).

### DETAILED DESCRIPTION OF THE DISCLOSURE

As defined herein, unless otherwise noted, all percentages expressed should be understood to be percentages by weight to the total weight of the composition. As used herein, the terms “layer” and “film” are used interchangeably.

In general, the disclosure features an etching composition (e.g., an etching composition for selectively removing HfOx) that includes (e.g., comprises or consists of) (1) at least one first acid or a salt thereof, the at least one first acid including a fluorine-containing inorganic acid; (2) at least one second acid different from the at least one first acid, the at least one second acid having a pKa of at most about 3; (3) at least one organic solvent having a logP of from about-0.2 to about 1.6; and (4) water. In some embodiments, the etching composition contains these four types of components only.

In some embodiments, the disclosure features an etching composition that includes (1) at least one first acid or a salt thereof, the at least one first acid including a fluorine-containing inorganic acid; (2) at least one second acid different from the at least one first acid, the at least one second acid having a pKa of at most about 3; (3) at least one organic solvent having a ClogP of from about-0.3 to about 1.6; and (4) water. In some embodiments, the etching composition contains these four types of components only.

In some embodiments, the etching composition of this disclosure includes at least one (e.g., two, three, or four) first acid or a salt thereof. In some embodiments, the first acid can be a fluorine-containing inorganic acid. In some embodiments, the first acid or a salt thereof can include hydrofluoric acid (HF), ammonium fluoride (NH₄F), ammonium hydrogen fluoride (NH₄F·HF), tetramethylammonium fluoride (TMAF), hexafluorosilicic acid (H₂SiF₆), Hexafluorophosphoric acid (HPF₆), or tetrafluoroboric acid (HBF₄). Without wishing to be bound by theory, it is believed that the first acid can facilitate the removal of HfOx on a semiconductor substrate during the etching process and enhance the HfOx etch selectivity.

In some embodiments, the first acid contained in an etching composition described herein can be in an amount that, in combination with the other materials of the etching composition, provides desired etching performance (e.g., desired HfOx etch rate and selectivity). In some embodiments, the first acid is in an amount of at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, at least about 1.5 wt %, at least about 1.6 wt %, at least about 1.8 wt %, or at least about 2 wt %) to at most about 5 wt % (e.g., at most about 4.5 wt %, at most about 4 wt %, at most about 3.5 wt %, at most about 3 wt %, at most about 2.8 wt %, at most about 2.6 wt %, at most about 2.5 wt %, at most about 2.4 wt %, at most about 2.2 wt %, or at most about 2 wt %) of an etching composition described herein.

In some embodiments, the etching composition of this disclosure can include at least one (e.g., two, three, or four) second acid different from the first acid. In some embodiments, the second acid is a strong acid and has a pKa ranging from at most about 3 (e.g., at most about 2.5, at most about 2, at most about 1.5, at most about 1, at most about 0.5, or at most about 0) to at least about-10 (e.g., at least about-9, at least about-8, at least about-7, at least about-6, or at least about-5). In some embodiments, the second acid does not include any fluorine atom. In some embodiments, the second acid can be an inorganic acid (e.g., hydrochloric acid, hydrobromic acid, nitric acid, phosphoric acid, sulfuric acid) or an organic acid (e.g., sulfonic acid). Without wishing to be bound by theory, it is believed that the second acid can keep the pH of the etching composition at a low level, and enhance the HfOx etch selectivity.

In some embodiments, the etching composition of this disclosure includes at least one (e.g., two, three, or four) organic solvent. In some embodiments, the organic solvent can have a ClogP (which represents partition coefficient) ranging from at least about-0.3 (e.g., at least about-0.2, at least about-0.15, at least about-0.1, at least about-0.05, at least about 0, at least about 0.05, at least about 0.1, at least about 0.15, at least about 0.2, at least about 0.25, or at least about 0.3) to at most about 1.6 (e.g., at most about 1.5, at most about 1.4, at most about 1.2, at most about 1, at most about 0.9, at most about 0.8, at most about 0.7, at most about 0.6, at most about 0.5, or at most about 0.4). Examples of organic solvent having the above ClogP values include alcohols such as ethanol, isopropanol, ethylene glycol monobutyl ether, 3-methoxy-3-methyl-1-butanol, benzyl alcohol, diethylene glycol monobutyl ether, and 4-methyl-2-pentanol; ketones such as cyclohexanone; and ethers such as tetrahydrofuran. As used herein, the ClogP values above are calculated by using a software ChemDraw and are summarized in Table 1 below.

TABLE 1

| Solvent | ClogP from ChemDraw |
|---|---|
| ethanol | −0.235 |
| isopropanol | 0.074 |
| ethylene glycol monobutyl ether | 0.841 |
| 3-methoxy-3-methyl-1-butanol | 0.423 |
| Benzyl alcohol | 1.104 |
| diethylene glycol monobutyl ether | 0.665 |
| 4-methyl-2-pentanol | 1.531 |
| cyclohexanone | 0.865 |
| tetrahydrofuran | 0.526 |

Without wishing to be bound by theory, it is believed that an organic solvent having a ClogP in the range described above can improve the HfOx/SiOx etch selectivity.

In some embodiments, the organic solvent is in an amount of at least about 80 wt % (e.g., at least about 82 wt %, at least about 84 wt %, at least about 85 wt %, at least about 86 wt %, at least about 88 wt %, at least about 90 wt %, at least about 92 wt %, at least about 94 wt %, or at least about 95 wt %) to at most about 99 wt % (e.g., at most about 98 wt %, at most about 97 wt %, at most about 96 wt %, or at most about 95 wt %) of an etching composition described herein.

In general, the etching composition of this disclosure can include water as a solvent. In some embodiments, the water can be de-ionized and ultra-pure, contain no organic contaminants, and/or have a minimum resistivity of about 4 to about 17 mega Ohms or at least about 17 mega Ohms. In some embodiments, the water is in an amount of from at least about 0.01 wt % (e.g., at least about 0.05 wt %, at least about 0.1 wt %, at least about 0.5 wt %, at least about 1 wt %, at least about 1.5 wt %, at least about 2 wt %, at least about 2.5 wt %, or at least about 3 wt %) to at most about 10 wt % (e.g., at most about 9 wt %, at most about 8 wt %, at most about 7 wt %, at most about 6 wt %, at most about 5 wt %, or at most about 4 wt %) of the etching composition. Without wishing to be bound by theory, it is believed that, if the amount of water is greater than 10 wt % of the composition, it would reduce HfOx/SiOx etching selectivity. On the other hand, without wishing to be bound by theory, it is believed that the etching composition of this disclosure should include a certain level of water (e.g., at least about 0.01 wt %) to avoid reduction in the etching performance.

In some embodiments, the etching composition of this disclosure can have a pH of at least about 0 (e.g., at least about 0.2, at least about 0.4, at least about 0.5, at least about 0.6, at least about 0.8, at least about 1, at least about 1.2, at least about 1,4, or at least about 1.5) and/or at most about 2 (e.g., at most about 1.8, at most about 1.6, at most about 1.5, at most about 1.4, at most about 1.2, at most about 1, at most about 0.8, at most about 0.6, or at most about 0.5). Without wishing to be bound by theory, it is believed that an etching composition having a pH lower than 0 would cause significant corrosion to other materials on a substrate. Further, without wishing to be bound by theory, it is believed that an etching composition having a pH higher than 2 would not have a sufficient HfOx removal rate.

In some embodiments, the cleaning compositions of this disclosure can optionally include at least one (e.g., two, three, or four) pH adjusting agent (e.g., an acid or a base) to control the pH to from about 0 to about 2. The amount of the pH adjusting agent required, if any, can vary as the concentrations of the other components (e.g., the first and second acids described herein) are varied in different formulation. In some embodiments, the pH adjusting agent can be at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, or at least about 1.5 wt %) and/or at most about 3 wt % (e.g., at most about 2.8 wt %, at most about 2.6 wt %, at most about 2.5 wt %, at most about 2.4 wt %, at most about 2.2 wt %, at most about 2 wt %, or at most about 1.8 wt %) of the etching composition. In some embodiments, the etching composition of this disclosure can be substantially free of a pH adjusting agent.

In some embodiments, the pH adjusting agent is free of any metal ion (except for a trace amount of metal ion impurities). Suitable metal ion free pH adjusting agents include acids and bases. Suitable acids that can be used as a pH adjusting agent include organic acids (e.g., carboxylic acids) and inorganic acids. Exemplary carboxylic acids include, but are not limited to, monocarboxylic acids, bicarboxylic acids, tricarboxylic acids, α-hydroxyacids and β-hydroxyacids of monocarboxylic acids, α-hydroxyacids or β-hydroxyacids of bicarboxylic acids, or α-hydroxyacids and β-hydroxyacids of tricarboxylic acids. Examples of suitable carboxylic acids include citric acid, maleic acid, fumaric acid, lactic acid, glycolic acid, oxalic acid, tartaric acid, succinic acid, and benzoic acid. Examples of suitable inorganic acids include phosphoric acid, nitric acid, sulfuric acid, and hydrochloric acid.

Suitable bases that can be used as a pH adjusting agent include ammonium hydroxide, monoamines (including alkanolamines), and cyclic amines. Examples of suitable monoamines include, but are not limited to, triethylamine, tributylamine, tripentylamine, diethylamine, butylamine, dibutylamine, and benzylamine. Examples of suitable alkanolamines include, but are not limited to, monoethanolamine, diethanolamine, triethanolamine, and aminopropyldiethanolamine. Examples of suitable cyclic amines include, but are not limited to, 1,8-diazabicyclo [5.4.0]-7-undecene (DBU), 1,5-diazabicyclo[4.3.0]-5-nonene (DBN), and octahydro-2H-quinolizine.

In some embodiments, the etching composition of the present disclosure can contain additives such as, pH adjusting agents, corrosion inhibitors, surfactants, additional organic solvents, biocides, and defoaming agents as optional components. Examples of certain suitable additives include alcohols (e.g., polyvinyl alcohol and sugar alcohols). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants can be cationic, anionic, nonionic, and amphoteric surfactants.

In general, the etching composition of the present disclosure can have a relatively high HfOx removal rate. In some embodiments, the etching composition can have a HfOx removal rate of from at least about 0.5 Å/min (e.g., at least about 1 Å/min, at least about 2 Å/min, at least about Å/min, at least about 5 Å/min, at least about 10 Å/min, at least about 15 Å/min, at least about 20 Å/min, at least about 25 Å/min, at least about 30 Å/min, at least about 35 Å/min, or at least about 40 Å/min) to at most about 100 Å/min (e.g., at most about 90 Å/min, at most about 80 Å/min, at most about 70 Å/min, at most about 60 Å/min, or at most about 50 Å/min) when a HfOx film is treated by the etching composition.

In general, the etching composition of the present disclosure can have a relatively low SiOx removal rate (e.g., a SiOx removal rate lower than the HfOx removal rate). In some embodiments, the etching composition can have a SiOx removal rate of from at least about 0.5 Å/min (e.g., at least about 1 Å/min, at least about 2 Å/min, at least about Å/min, at least about 5 Å/min, at least about 10 Å/min, at least about 15 Å/min, at least about 20 Å/min, at least about 25 Å/min, at least about 30 Å/min, at least about 35 Å/min, or at least about 40 Å/min) to at most about 100 Å/min (e.g., at most about 90 Å/min, at most about 80 Å/min, at most about 70 Å/min, at most about 60 Å/min, or at most about 50 Å/min) when a SiOx film is treated by the etching composition.

In general, the etching composition of the present disclosure can have a relatively high HfOx/dielectric material (e.g., SiOx such as SiO₂, or SiOCN) removal rate selectivity (i.e., a high ratio of HfOx removal rate over dielectric material removal rate). In some embodiments, the etching composition can have a SiN/SiOx removal rate selectivity of at least about 1 (e.g., at least about 1.5, at least about 2, at least about 2.5, at least about 3, at least about 3.5, at least about 4, at least about 4.5, or at least about 5) and/or at most about 10 (e.g., at most about 9, at most about 8, at most about 7, at most about 6, or at most about 5) when the etch rates of HfOx and SiOx are measured under the same conditions (e.g., at the same etching temperature).

In some embodiments, the etching compositions of the present disclosure can be substantially free of one or more of additive components, in any combination, if more than one. Such components are selected from the group consisting of polymers (e.g., non-ionic, cationic, or anionic polymers), oxygen scavengers, quaternary ammonium compounds (e.g., salts or hydroxides), alkaline bases (such as NaOH, KOH, LiOH, Mg(OH)₂, and Ca(OH)₂), surfactants (e.g., cationic, anionic, or non-ionic surfactants), defoamers, fluorine-containing compounds (e.g., fluoride compounds or fluorinated compounds (such as fluorinated polymers/surfactants)) other than fluorine-containing inorganic acids or salts thereof, silicon-containing compounds such as silanes (e.g., alkoxysilanes) other than described herein, nitrogen-containing compounds other than described herein (e.g., amino acids, amines, imines (e.g., amidines such as 1,8-diazabicyclo [5.4.0]-7-undecene (DBU) and 1,5-diazabicyclo[4.3.0]non-5-ene (DBN)), amides, or imides), abrasives (e.g., ceria abrasives, non-ionic abrasives, surface modified abrasives, negatively/positively charged abrasive, or ceramic abrasive composites), plasticizers, oxidizing agents (e.g., peroxides such as hydrogen peroxide, and periodic acid), corrosion inhibitors (e.g., azole or non-azole corrosion inhibitors), electrolytes (e.g., polyelectrolytes), silicates, cyclic compounds other than described herein (e.g., azoles (such as diazoles, triazoles, or tetrazoles), triazines, and cyclic compounds containing at least two rings such as substituted or unsubstituted naphthalenes, or substituted or unsubstituted biphenylethers), chelating or complexing agents, buffering agents, acids such as organic acids (e.g., carboxylic acids such as hydroxycarboxylic acids, polycarboxylic acids, and sulfonic acid) and inorganic acids (e.g., sulfuric acid, sulfurous acid, nitrous acid, nitric acid, phosphorous acid, and phosphoric acid), salts (e.g., halide salts or metal salts), and catalysts (e.g., metal-containing catalysts). In some embodiments, the composition is substantially free of an oxidizing agent, a complexing agent, a surfactant, or an amine. As used herein, a component that is “substantially free” from an etching composition refers to an ingredient that is not intentionally added into the etching composition. In some embodiments, the etching composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above components that are substantially free from the etching composition. In some embodiments, the etching compositions described herein can be completely free of one or more of the above components.

The etching composition of this disclosure can be prepared by simply mixing the components together, or can be prepared by blending two or more compositions (each containing certain components of an etching composition described herein) in a kit.

In some embodiments, the present disclosure features a method of etching a semiconductor substrate that includes a HfOx film (e.g., in a HfOx-containing feature). The method can include contacting a semiconductor substrate containing the HfOx film with an etching composition described herein to substantially remove the HfOx film. In some embodiments, the semiconductor substrate can include a pattern or a feature on a surface and the HfOx film is a part of the pattern or feature. In some embodiments, the method can further include rinsing the semiconductor substrate with a rinse solvent after the contacting step and/or drying the semiconductor substrate after the rinsing step.

In some embodiments, the contacting step can be performed either at room temperature (i.e., 23° C.) or at an elevated temperature. For example, the contacting step can performed at a temperature ranging from at least about 23° C. (e.g., at least about 25° C., at least about 30° C., at least about 35° C., or at least about 40° C.) to at most about 50° C. (e.g., at most about 45° C., at most about 40° C., at most about 35° C., or at most about 30° C.). Without wishing to be bound by theory, it is believed that performing the contacting step at an elevated temperature (e.g., in the range described above) can increase the HfOx etch rate of the etching composition.

In some embodiments, the method does not substantially remove a metal conductor (e.g., Cu) or a dielectric material (e.g., SiOx or SiOCN) in the semiconductor substrate. For example, the method does not remove more than about 5% by weight (e.g., more than about 3% by weight or more than about 1% by weight) of a metal conductor or a dielectric material in the semiconductor substrate.

In some embodiments, the etching method includes the steps of:
(A) providing a semiconductor substrate containing a HfOx film (e.g., a HfOx film in a pattern or feature);
(B) contacting the semiconductor substrate with an etching composition described herein;
(C) rinsing the semiconductor substrate with one or more suitable rinse solvents; and
(D) optionally, drying the semiconductor substrate (e.g., by any suitable means that removes the rinse solvent and does not compromise the integrity of the semiconductor substrate).

The semiconductor substrates to be etched in this method can contain organic and organometallic residues, and a range of metal oxides, some or all of which may also be removed during the etching process.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates can also contain layers of interlayer dielectrics, polysilicon, silicon oxide, silicon nitride, silicon germanium, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of from at least about 20° C. to about 60° C. The etch rates of HfOx increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in single wafer process, a suitable time range is, for example, up to about 10 minutes (e.g., from about 1 minute to about 7 minutes, from about 1 minute to about 5 minutes, or from about 0.5 minutes to about 4 minutes). Etching times for an immersion batch type process can range from about 30 seconds to about 60 minutes (e.g., from about 1 minute to about 60 minutes, from about 10 minutes to about 60 minutes, from about 20 minutes to about 60 minutes, or from about 30 minutes to about 60 minutes).

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate, and propylene glycol monomethyl ether acetate. Alternatively, or in addition, aqueous rinses with pH>8 (such as dilute aqueous ammonium hydroxide) can be employed. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16° C. and 27° C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying, and any combinations thereof. Drying times will be dependent on the specific method employed but are typically on the order of 30 seconds up to several minutes.

In some embodiments, the etching method described herein further includes forming a semiconductor device (e.g., an integrated circuit device such as a semiconductor chip) from the semiconductor substrate obtained by the method described above.

While the invention has been described in detail with reference to certain embodiments thereof, it will be understood that modifications and variations are within the spirit and scope of that which is described and claimed.

The present disclosure is illustrated in more detail with reference to the following examples, which are for illustrative purposes and should not be construed as limiting the scope of the present disclosure.

### EXAMPLES

### General Procedure 1

### Formulation Blending

Samples of etching compositions were prepared by adding, while stirring, to the calculated amount of the solvent the remaining components of the formulation.

### GENERAL PROcedure 2

### Materials and Methods

Blanket film etch rate measurements on films were carried out using commercially available unpatterned 300 mm diameter wafers that were diced into 1.5 cm×5.0 cm test coupons for evaluation. Primary blanket film materials used for testing included 1) a HfOx film having a thickness of about 200 Å deposited on a silicon substrate and 2) a SiOx film having a thickness of about 1000 Å deposited on a silicon substrate.

The blanket film test coupons were measured for pre-treatment and post-treatment thickness to determine blanket film etch rates. For the HfOx and SiOx blanket films, the film thicknesses were measured pre-treatment and post-treatment by Ellipsometry using a Woollam VASE at three points for each coupon.

### General Procedure 3

### Etching Evaluation with Beaker Test

All blanket film etch testing was carried out in a 500 ml PTFE beaker containing 200 g of a sample solution with continuous stirring at 250 rpm. The beaker was put on a hot stirrer and set at a desired temperature. All blanket test coupons having a blanket film exposed on one side to the sample solution were diced by diamond scribe into 1.5 cm×2.0 cm test coupon size for beaker scale testing. Each individual test coupon was held into position using a single 4″ long, locking plastic tweezers clip. The test coupon, held on one edge by the locking tweezers clip, was suspended into the 500 ml PTFE beaker and immersed into the 200 g test solution while the solution was stirred continuously at 250 rpm at 23° C. The test coupons were held static in the stirred solution until the treatment time (1 minute, 3 minutes, or 10 minutes) had elapsed.

After the treatment time had elapsed, the sample coupons were immediately removed from the 500 ml PTFE beaker and rinsed. Specifically, the coupon was immersed in a 200 mL of isopropyl alcohol (IPA) for 15 seconds with mild agitation, which was followed by immersion in 200 mL of ultra-high purity deionized (DI) water for 20 seconds with mild agitation. After the final rinse step, all test coupons were subject to a filtered nitrogen gas blow off step using a hand held nitrogen gas blower which forcefully removed all traces of IPA to produce a final dry sample for test measurements.

### Example 1

Formulation Examples 1-34 (FE-1 to FE-34) were prepared according to General Procedure 1, and evaluated according to General Procedures 2 and 3. The formulations of FE-1 to FE-34 are summarized in Table 2 and the test results are summarized in Table 3. In Table 3, the HfO₂ etch rates were measured after immersing a test coupon in a formulation for 1 minute or 3 minutes at 23° C., and the SiO₂ etch rates were measured after immersing a test coupon in a formulation for 10 minutes at 23° C.

TABLE 2

| | Fluorine- | | | | Main | |
|---|---|---|---|---|---|---|
| | Containing | HCl | Water | Co-Solvent | Solvent | |
| Formulations | acid (wt %) | (wt %) | (wt %) | (wt %) | (wt %) | Total |
| FE-1 | HF (1.2%) | 0.4% | 3.4% | None | MMB (remainder) | 100% |
| FE-2 | HF (1.09%) | 0.36% | 3.09% | MMB (20%) | 2-Ethyl hexanol | 100% |
| | | | | | (remainder) | |
| FE-3 | HF (1.2%) | 0.4% | 3.4% | MMB (10%) | 2-Ethyl hexanol | 100% |
| | | | | | (remainder) | |
| FE-4 | HF (1.2%) | 0.4% | 3.4% | MMB (30%) | Benzyl alcohol | 100% |
| | | | | | (remainder) | |
| FE-5 | HF (1.2%) | 0.4% | 3.4% | None | Isopropanol | 100% |
| | | | | | (remainder) | |
| FE-6 | HF (1.2%) | 0.4% | 3.4% | None | Methanol (remainder) | 100% |
| FE-7 | HF (1.2%) | 0.4% | 3.4% | None | Ethanol (remainder) | 100% |
| FE-8 | HF (1.2%) | 0.4% | 3.4% | None | DMSO (remainder) | 100% |
| FE-9 | HF (1.2%) | 0.4% | 3.4% | None | EGBE (remainder) | 100% |
| FE-10 | HF (1.2%) | 0.4% | 3.4% | None | Cyclohexanone | 100% |
| | | | | | (remainder) | |
| FE-11 | HF (1.2%) | 0.4% | 3.4% | None | THF (remainder) | 100% |
| FE-12 | HF (1.2%) | 0.4% | 3.4% | None | 1,2-Propanediol | 100% |
| | | | | | (remainder) | |
| FE-13 | HF (1.2%) | 0.4% | 3.4% | None | MMB (remainder) | 100% |
| FE-14 | HF (2%) | 0.4% | 4.6% | None | MMB (remainder) | 100% |
| FE-15 | HF (2.8%) | 0.4% | 5.8% | None | MMB (remainder) | 100% |
| FE-16 | HF (0.8%) | 0.4% | 2.8% | None | MMB (remainder) | 100% |
| FE-17 | HF (0.2%) | 0.4% | 1.9% | None | MMB (remainder) | 100% |
| FE-18 | H₂SiF₆ (5.1%) | None | 9.9% | None | MMB (remainder) | 100% |
| FE-19 | HF (1.2%) | 0.4% | 3.4% | None | DEGBE (remainder) | 100% |
| FE-20 | HF (1.09%) | 0.36% | 3.09% | MMB (20%) | 4-Methyl-2-pentanol | 100% |
| | | | | | (remainder) | |
| FE-21 | HF (1.2%) | 0.4% | 3.4% | None | PC (remainder) | 100% |
| FE-22 | HF (1.2%) | 0.4% | 3.4% | None | Sulfolane (remainder) | 100% |
| FE-23 | HF (1.2%) | 0.4% | 3.4% | DMSO (20%) | MMB (remainder) | 100% |
| FE-24 | HF (1.2%) | 0.4% | 3.4% | PC (20%) | MMB (remainder) | 100% |
| FE-25 | HF (2.8%) | 0.4% | 4.22% | None | MMB (remainder) | 100% |
| FE-26 | HF (2%) | 0.4% | 4.6% | None | MMB (remainder) | 100% |
| FE-27 | HF (2.8%) | 0.4% | 5.8% | None | MMB (remainder) | 100% |
| FE-28 | HF (2.8%) | None | 4.2% | None | MMB (remainder) | 100% |
| FE-29 | HF (1.2%) | 0.4% | 3.4% | None | MMB (remainder) | 100% |
| FE-30 | HF (2.8%) | 0.4% | 3.48% | None | MMB (remainder) | 100% |
| FE-31 | HF (2.8%) | 0.4% | 3.48% | MEK (10%) | MMB (remainder) | 100% |
| FE-32 | HF (2.8%) | 0.4% | 3.48% | MEK (20%) | MMB (remainder) | 100% |
| FE-33 | HF (2.8%) | 0.4% | 3.48% | Xylene (10%) | MMB (remainder) | 100% |
| FE-34 | HF (2.8%) | 0.4% | 3.48% | Xylene (20%) | MMB (remainder) | 100% |

MMB = 3-methoxy-3-methyl-1-butanol
EGBE = ethylene glycol monobutyl ether
DEGBE = diethylene glycol monobutyl ether
PC = Propylene carbonate
MEK = methyl ethyl ketone

TABLE 3

| | Process | As deposited | HfO₂ ER (Å/min) | FCVD | PEALD | |
|---|---|---|---|---|---|---|
| | temperature | HfO₂ ER | after 300 min | SiO₂ ER | SiO₂ ER | HfO₂/SiO₂ |
| Formulations | (° C.) | (Å/min) | annealing at 500° C. | (Å/min) | (A/min) | selectivity |
| FE-1 | RT | 3.9 | | 1.2 | | 3.3 |
| FE-2 | RT | 22.7 | | 217.1 | | 0.1 |
| FE-3 | RT | 32.9 | | 90.2 | | 0.4 |
| FE-4 | RT | 18.3 | | 33.8 | | 0.5 |
| FE-5 | RT | 3.5 | | 2.3 | | 1.5 |
| FE-6 | RT | 2.1 | | 2.1 | | 1 |
| FE-7 | RT | 2.5 | | 2 | | 1.2 |
| FE-8 | RT | 0.4 | | 0.9 | | 0.5 |
| FE-9 | RT | 8.9 | | 12.9 | | 0.7 |
| FE-10 | RT | 15.3 | | 38.8 | | 0.4 |
| FE-11 | RT | 4.4 | | 3.7 | | 1.2 |
| FE-12 | RT | 1.3 | | 2.2 | | 0.6 |
| FE-13 | 40 | 7.2 | | 3.7 | | 1.9 |
| FE-14 | RT | 6.5 | | 2.8 | | 2.3 |
| FE-15 | RT | 12.7 | | 7.6 | | 1.7 |
| FE-16 | 40 | 3.5 | | 1.1 | | 3.2 |
| FE-17 | 40 | 1.2 | | 0.5 | | 2.2 |
| FE-18 | RT | 1.1 | | 1.3 | | 0.9 |
| FE-19 | RT | 4.1 | | 2.2 | | 1.8 |
| FE-20 | RT | 8.5 | | 6.7 | | 1.3 |
| FE-21 | RT | 41.7 | | 110.3 | | 0.4 |
| FE-22 | RT | 18.4 | | 35.1 | | 0.5 |
| FE-23 | RT | 0.9 | | 1.2 | | 0.7 |
| FE-24 | RT | 2.1 | | 1 | | 2 |
| FE-25 | RT | | 15 | | 2.8 | 5.4 |
| FE-26 | RT | | 7.5 | | 2 | 3.7 |
| FE-27 | RT | | 22 | | 4.4 | 5 |
| FE-28 | RT | | 12 | | 2.8 | 4.3 |
| FE-29 | 20 | | 21 | | 4.9 | 4.3 |
| FE-30 | RT | 8.6 | | | 2.8 | 3.1 |
| FE-31 | RT | 9.3 | | | 3.2 | 2.9 |
| FE-32 | RT | 10.5 | | | 3.6 | 2.9 |
| FE-33 | RT | 13.9 | | | 5.7 | 2.4 |
| FE-34 | RT | 17.2 | | | 7 | 2.5 |

RT = Room temperature
ER = Etch rate
FCVD SiO₂ = SiO₂ made by flowable chemical vapor deposition
PEALD SiO₂ = SiO₂ made by plasma enhanced atomic layer deposition

In general, it is desirable for the etching composition to have a HfOx etch rate of at least about 3 Å/min, a SiOx etch rate of at most about 5 Å/min, and a HfOx/SiOx etch rate selectivity of at least about 1. As shown in Table 3, a large number of tested formulations exhibited the above properties.

While the invention has been described in detail with reference to certain embodiments thereof, it will be understood that modifications and variations are within the spirit and scope of that which is described and claimed.

What is claimed is:

1. An etching composition, comprising:
at least one first acid or a salt thereof, the at least one first acid comprising a fluorine-containing inorganic acid;
at least one second acid different from the at least one first acid, the at least one second acid having a pKa of at most about 3;
at least one organic solvent having a ClogP of from about-0.3 to about 1.6; and
water.

2. The composition of claim 1, wherein the at least one first acid or a salt thereof comprises HF, NH₄F, NH₄F·HF, TMAF, H₂SiF₆, HPF₆, or HBF₄.

3. The composition of claim 1, wherein the at least one first acid or a salt thereof is in an amount of from about 0.1 wt % to about 5 wt % of the composition.

4. The composition of claim 1, wherein the at least one second acid comprises hydrochloric acid, hydrobromic acid, nitric acid, phosphoric acid, sulfuric acid, or a sulfonic acid.

5. The composition of claim 1, wherein the at least one second acid is in an amount of from about 0.01 wt % to about 1 wt % of the composition.

6. The composition of claim 1, wherein the at least one organic solvent has a ClogP of from about 0.2 to about 0.8.

7. The composition of claim 1, wherein the at least one organic solvent comprises ethanol, isopropanol, tetrahydrofuran, ethylene glycol monobutyl ether, 3-methoxy-3-methyl-1-butanol, diethylene glycol monobutyl ether, 4-methyl-2-pentanol, or cyclohexanone.

8. The composition of claim 1, wherein the at least one organic solvent is in an amount of from about 80 wt % to about 99 wt % of the composition.

9. The composition of claim 1, wherein the water is in an amount of from about 0.01 wt % to about 10 wt % of the composition.

10. The composition of claim 1, wherein the composition has a pH of from about 0 to about 2.

11. The composition of claim 1, wherein the composition is substantially free of an oxidizing agent, a complexing agent, a surfactant, or an amine.

12. The composition of claim 1, wherein the composition consists of the at least one first acid, at least one second acid, at least one organic solvent, and water.

13. An etching composition, comprising:
at least one first acid or a salt thereof, the at least one first acid comprising a fluorine-containing inorganic acid;
at least one organic solvent having a ClogP of from about-0.3 to about 1.6; and
water.

14. A method, comprising:
contacting a semiconductor substrate supporting a hafnium oxide film with a composition of claim 1 to substantially remove the hafnium oxide film.

15. The method of claim 14, wherein a pattern is formed on a surface of the semiconductor substrate and the hafnium oxide film is a part of the pattern.

16. The method of claim 14, wherein the method does not substantially remove silicon oxide.

17. An article formed by the method of claim 14, wherein the article is a semiconductor device.

18. The article of claim 17, wherein the semiconductor device is an integrated circuit.
